(19) United States
(12) Patent Application Publication
(10) Pub. No.: US 2015/0292080 A1
(43) Pub. Date: Oct. 15, 2015

(54) APPARATUS FOR THE GENERATION OF NANOCLUSTER FILMS AND METHODS FOR DOING THE SAME

(71) Applicant: Nanyang Technological University, Singapore (SG)

(72) Inventors: Siu Hon TSANG, Singapore (SG); Naiyun XU, Singapore (SG); Hang Tong Edwin TEO, Singapore (SG); Beng Kang TAY, Singapore (SG)

(21) Appl. No.: 14/376,999

(22) PCT Filed: Feb. 6, 2013
(86) PCT No.: PCT/SG2013/000050

§ 371 Date: Aug. 6, 2014

Related U.S. Application Data
(60) Provisional application No. 61/595,346, filed on Feb. 6, 2012.

(51) Int. Cl. C23C 14/32; B01J 37/34; B01J 23/06; B01J 23/75; C23C 14/06; C23C 14/14

(52) U.S. Cl. CPC C23C 14/325; C23C 14/0605; C23C 14/14; B01J 23/06; B01J 23/75; B01J 37/349

(57) ABSTRACT

A filtered cathodic vacuum arc apparatus and method for the generation of a nanocluster film or compound film with improved characteristics onto a substrate and thin film materials, carbon-encapsulated metal nanoclusters and carbon nanotubes formed through the use of said apparatus and method. The apparatus includes a deposition chamber, a substrate holder for holding a substrate within the deposition chamber, means for simultaneously generating a first beam of plasma and a second beam of plasma from a first and a second plasma source, respectively, a Y-bend magnetic filter to direct the plasma towards a substrate on the substrate holder and an anti-Helmholtz coil set-up within the deposition chamber, wherein the Y-bend magnetic filter and anti-Helmholtz coil set up cause first and second beams of plasma to mix.

### FIELD

This application relates to an apparatus for the generation of a nanocluster film or a compound film.

### BACKGROUND

The listing or discussion of a prior-published document in this specification should not necessarily be taken as an acknowledgement that the document is part of the state of the art or is common general knowledge.

Nanoclusters are aggregates of atoms that contain from a few atoms to a few thousand atoms, in which crucial size-dependent properties such as the quantum confinement effect can be engineered for nanotechnology applications³. However, due to the large surface-to-volume ratio of nanoclusters, drawbacks such as material deterioration, cluster aggregation and chemical instability become an inevitable challenge to control⁴. Through the infusion of Nanoclusters into a matrix material, the nanoclusters are encapsulated from ambient conditions and hence are applicable for device fabrications⁵.

Conventionally, there are various methods to synthesize nanoclusters, such as, chemical reactions⁶, ion sputtering, implantation⁷ and cluster beam deposition⁸. In general, the process used in the synthesis of the nanoclusters is strongly dependent on the chemical structure of the material, generally provides insufficient control over the density and the uniformity of the nanocluster and also little or no intermixing capability to enable compound nanocluster generation.

Carbon nanotubes (CNTs) are allotropes of carbon with a cylindrical nanostructure that possess extraordinary intrinsic properties for thermal, electrical and mechanical applications¹⁵. Commercial CNTs are commonly produced by the Chemical Vapor Deposition (CVD) method. For CVD, typically, the process involves the preparation of the metal catalyst which requires the deposition of a thin layer of metal catalyst (˜1-10 nm) and subsequently a thermal treatment (˜600° C.) to produce metal clusters before the growth of CNTs. The CVD method involves multiple process steps and the CNTs usually suffer from large boundary resistances (thermal and electrical)¹⁶.

Owing to their high chemical and thermal stabilities, carbon encapsulated Ni nanoparticles have recently received considerable attention^{17, 18, 19}. This attention has been especially focussed on magnetic applications because of the potential to have small magnetic clusters with preserved surface spin, large coercive force, enhanced signal to noise ratio when reading/writing and reduced magnetic coupling between individual clusters, all of which leads towards ultra-high density magnetic storage applications ^{20, 21, 22, 23, 24}. In addition, carbon thin films possess versatile mechanical, thermal and electrical properties dependent on the configuration of its hybridization²⁵. For example, graphite possesses one of the highest thermal conductivities in the horizontal direction (parallel to its basal planes) but four orders of magnitude lower thermal conductivity in the perpendicular direction, due to the anisotropic nature of the crystalline configuration. Vertically orientated nanocrystalline graphite (NCG) films are known to have excellent thermal conductivity in the vertical direction, due to the formation of graphitic basal planes perpendicular to the substrate. The thermal conductivity of such a film was found to be 16.72 W/m K, as compared to amorphous carbon film of 0.95 W/m K²⁶. However, no methods are currently known that can make a textured carbon as the matrix for nickel nanoclusters, such a method would enable a higher quality film. There currently exists a need to find better ways to make compound nanoclusters, carbon nanotubes and carbon encapsulated Ni nanoparticles.

Filtered Cathodic Vacuum Arc (FCVA) techniques, an arc-evaporation plasma deposition method², have been previously disclosed by the current inventors¹ and others. The inventors have surprisingly found that the FCVA technique and apparatus can be adapted for use in the formation of compound nanoclusters, carbon encapsulated Ni nanoparticles and compound nanoclusters for use as a catalyst to make superior carbon nanotubes.

### SUMMARY OF THE INVENTION

The present invention aims to provide a new method for the production of nanoclusters, and their infusion into a film to form a nanocluster film. It further aims to provide a hardware design, prototype development and a new methodology for the generation of compound nanoclusters.

This technology is based on the FCVA technique, whereby parameters that govern the deposition, such as the ion density and energy of the plasma, can be adjusted according to the required application. In general terms the invention proposes a new design of the magnetic filter (a Y-bend filter) that couples with two target sources for the simultaneous production of two separate plasmas in a single deposition process. An electromagnetic component that is based on the engineering of the magnetic field has also been developed to provide an additional medium to control the intermixing of the two plasmas and therefore, the properties of the generated nanoclusters.

In embodiments of the invention, the ion density and energy of the two plasma sources can be adjusted independently to provide a mode of control for the parameters of the nanoclusters. Furthermore, the FCVA technique is capable of depositing a wide range of materials². As discussed herein, the interaction of the two plasmas is established with the Y- bend filter by channelling the two plasma beams into one. This interaction is further enhanced with a controllable condensation of the plasma density before the nucleation and the growth of the nanocluster film.

Furthermore, with the capability of intermixing two different sources, nanoclusters in a matrix film can be formed and hence, provide a new platform for the development of complex atomic nanocluster physics.

In an aspect of the invention, there is disclosed a filtered cathodic vacuum arc (FCVA) apparatus for the generation of a nanocluster film or a compound film on a substrate, comprising: a deposition chamber; a substrate holder for holding a substrate; means for simultaneously generating a first beam of plasma and a second beam of plasma from a first and a second plasma source, respectively; a Y-bend magnetic filter that connects the first and second plasma sources with the deposition chamber, the Y-bend filter comprising a single stem, a first arm and a second arm, with the first arm connecting the first plasma source to the stem, and the second arm connecting the second plasma source to the stem, and the stem connecting the first and second arms to the deposition chamber, at least the first and second arms containing respective magnetic field generation means for guiding the first beam of plasma and the second beam of plasma respectively along the first and second arms; and an anti-Helmholtz coil set-up within the deposition chamber that is adapted to provide a magnetic confinement for the plasma generated from the first and second plasma sources, and which comprises a first and a second electromagnetic coil, wherein, the Y-bend magnetic filter is adapted to channel the plasma from the first and second plasma sources together in a first stage interaction and the anti-Helmholtz coil set-up is adapted to establish a second stage interaction between the respective the first and second plasmas by magnetic confinement. In embodiments of the invention, the apparatus is for the generation of a nanocluster film.

In an embodiment, the Y-bend magnetic filter further comprises a focusing coil attached to the stem. In yet further embodiments, the first and second arms of the Y-bend magnetic filter each comprise a first bend and a second bend.

In yet further embodiments, the means for simultaneously generating a beam of positive ions in the form of plasma from a first and a second plasma source is a first anode-cathode assembly attached to the first plasma source and a second anode-cathode assembly attached to the second plasma source.

In embodiments of the invention, the first plasma source is carbon or a metal and the second plasma source is a metal. For example, the second plasma source is selected from zinc, nickel, aluminium and iron. For example, when the first source is a metal, it can be selected from zinc, nickel, aluminium and iron, provided that the first source is not the same as the second source. In yet still further embodiments, the apparatus further comprises: means for independently controlling the energy of the first and second plasma beams, optionally wherein the means is supplied by a first and second current controlled attached to the first plasma source and the second plasma source, respectively; and/or means for independently controlling the density of the first and second plasma beams, optionally wherein the means is supplied by a first and second tuning controller that tune the magnetic field produced in the first arm and the second arm of the Y-bend magnetic filter, respectively.

In yet still further embodiments, the anti-Helmholtz coil further comprises a current controller for independent control of the first and second electromagnetic coils.

In a further aspect of the invention, there is disclosed a process for the deposition of a compound nanocluster film onto a substrate, using the herein before disclosed FCVA apparatus, comprising the steps of:
(a) simultaneously and independently generating a first beam and a second beam of plasma from a first plasma source and a second plasma source, respectively (e.g. the generation of the first beam and second beam of plasma is accomplished by the use a first and second anode-cathode array attached to the first and second plasma source, respectively; and/or the energy of the first beam and the second beam is independently controlled by adjusting the electrical current of the first or second plasma source, respectively;
(b) independently directing the first beam and second beam of plasma through a first arm and second arm, respectively, of a Y-bend magnetic filter towards a connective stem of the Y-bend magnetic filter fluidly connected to both arms (e.g. the direction of the first beam of plasma and the second beam of plasma is accomplished by the use of magnetic filters attached to the first and second arms of the Y-bend magnetic filter; and/or the density of the first beam of plasma and the second beam of plasma is controlled by tuning the strength of the magnetic field of the Y-bend filter);
(c) mixing the first and second beams of plasma together in the connective stem of the Y-bend magnetic filter in a first stage interaction;
(d) directing the mixed plasma of the first stage interaction towards an electromagnetic magnetic containment field situated in a deposition chamber (e.g. the direction of the mixed plasma of the first stage interaction is accomplished by a focusing coil attached to the connective stem of the Y-ben magnetic filter);
(e) further mixing the mixed plasma of the first stage interaction together in a second stage interaction within the electromagnetic containment field; and
(f) depositing the mixed plasma generated by the second stage interaction onto a substrate situated in the deposition chamber to form a nanocluster film.

In embodiments of the invention, the magnetic containment field is generated by said anti-Helmhotz coil set-up, said first and second electromagnetic coils independently producing substantially identical but opposed electromagnetic fields. In a further embodiment, the first and second electromagnetic coils operate using a current from 0.5 A to 20 A, optionally from 2.5 A to 15 A, such as from 5 A to 10 A.

In a further embodiment of the invention, the process can further comprise a step (g) where carbon nanotubes are formed from the nanocluster film deposited onto the substrate in step (f) of the process disclosed hereinbefore.

In yet a further embodiment of the invention, wherein the first plasma source is carbon and the second plasma source is a metal. For example the second plasma source is selected from zinc, nickel, aluminium and iron. For example, when the first source is a metal, it can be selected from zinc, nickel, aluminium and iron, provided that the first source is not the same as the second source. In a yet further aspect of the invention, there is disclosed a compound nanocluster thin film and/or compound nanocluster thin film catalyst for the synthesis of carbon nanotubes obtained or obtainable by the processes disclosed hereinbefore. For example, the nanocluster film used in said process is made of cobalt nanoclusters embedded in a carbon matrix and the carbon nanotubes are formed by a chemical vapour deposition process using C₂H₂ and NH₃ at 650° C. In a yet further aspect, there is disclosed a carbon nanotube obtained or obtainable from the process of generating a carbon nanotube from a compound nanocluster catalyst as disclosed hereinbefore.

In a yet further aspect, there is disclosed a carbon encapsulated metal nanocluster obtained or obtainable by the process disclosed hereinbefore.

### BRIEF DESCRIPTION OF THE FIGURES

Preferred embodiments will now be described with reference to the accompanying figures in which:

FIG. 1a is a schematic of the Y-bend FCVA deposition apparatus;

FIG. 1b is an image of the Y-bend FCVA deposition apparatus;

FIG. 2 is a schematic illustrating the intermixing of two plasmas in magnetic confinement produced by anti-Helmholtz coils and provides an approximation of the positioning of the substrate holder (and hence the substrate);

FIG. 2a is a schematic of the Y-bend magnetic filter, showing the double bends in each of the arms of the filter;

FIG. 2b is an image of the Y-bend magnetic filter;

FIG. 3 is a schematic of the magnetic confinement and similarity between a permanent magnet and an electromagnet;

FIG. 4a is a simulation of the formation of the magnetic trap;

FIG. 4b depicts the density of plasma observed in a functioning magnetic trap;

FIG. 5 depicts scanning electron microscope images of deposited nanocluster films with a magnetic trap set at 0 A, 5 A and 10 A;

FIG. 6 shows an energy-dispersive X-ray (EDX) of the nanocluster film produced using a magnetic trap set at 10 A, also depicted in FIG. 5, with point scan and area scans that confirm the presence of Zn clusters and its density;

FIG. 7a (prior art) is a schematic depicting the preparation of a catalyst and growth of carbon nanotubes using conventional technology;

FIG. 7b is a schematic depicting the preparation of catalyst and growth of carbon nanotubes using the apparatus and method of the current invention; and

FIG. 8 depicts scanning electron microscope images of the CNTs synthesized using the method and apparatus of the current invention at two different magnifications (600× and 20,000×). Bundles of CNTs are observed as a result of the nanocluster catalyst.

FIG. 9 depicts a schematic of a carbon based material as a next generation thermal interface material (TIM). Nanoclusters are used to improve the thermal boundary resistance between CNT and substrate.

FIG. 10 depicts a schematic of a Ni nanocluster-infused NCG film for high temperature magnetic storage applications.

FIG. 11 shows a cross sectional transmission electron microscopy (TEM) image of Ni nanoclusters infused with NCG film, prepared using the apparatus and methods disclosed in this application. The dark circular structures correspond to Ni nanoclusters and the lighter grey region (with graphitic planes perpendicular to the substrate) corresponds to the NCG film. The bottom region is the substrate.

### DETAILED DESCRIPTION OF PREFERRED EMBODIMENTS

Embodiments of the present invention will be described more fully hereinafter with reference to the accompanying drawings. As those skilled in the art would realize, the described embodiments may be modified in various different ways without departing from the scope of the present invention.

In the drawings, dimensions of layers, regions, etc., are exaggerated for clarity. Like reference numerals designate like elements throughout the specification and the drawings.

When referred to herein the terms “plasma source”, “plasma target” are interchangeable unless otherwise indicated.

When referred to herein the terms “arc source” and “arc supply” are interchangeable unless otherwise indicated.

In all embodiments of the invention disclosed herein, terms such as “comprises” or “comprising of” can be replaced by terms such as “consists of” and “consisting of”.

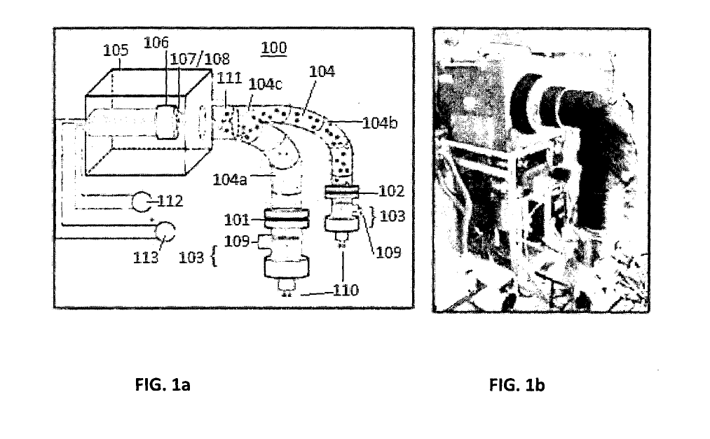

In an embodiment of the invention, the FCVA apparatus is described with reference to FIGS. 1a and 1b.

The schematic of the deposition apparatus (100) is shown in FIG. 1a. This system consists of two plasma sources (i.e. a first and a second plasma source; 101, 102), each attached to an anode and cathode assembly, 103), a Y-bend magnetic filter (104) that connects the plasma sources with the deposition (or vacuum) chamber (105), an anti-Helmholtz coil setup (106) that is designed to provide a magnetic confinement for the plasma and a substrate holder (107).

As depicted, the substrate holder contains a substrate (108) for deposition of the plasmas generated from the plasma sources (101, 102). The anode and cathode assembly (103) comprises a striker (109) and arc supply (110). In the embodiment shown, the first plasma source can be a carbon source and the second plasma source can be a metal source for the generation of carbon and metal ions, respectively. Heating and a source of electricity are supplied to the deposition chamber via the heater (112) and electrical bias supply (113), respectively. Figure lb shows the image of the actual setup of the apparatus.

a. The generation of plasma and the Y-bend magnetic filter

The plasma sources (or targets) are connected to an arc supply (110) within the anode-cathode assembly (103) while the striker (109) is connected to ground. When a contact is made, an arc is generated and plasma is formed. The ion energy of the two independent plasmas can be controlled by adjusting the electrical current of the respective arc source. The anode-cathode assembly is of standard construction and is described in US 2003/085123 and U.S. Pat. No. 6,262,539.

Due to the charged-nature of the plasma, the magnetic field generated by the Y-bend magnetic filter (104) produces a steering force (Lorentz force), acting perpendicularly to the momentum of the charged particle and hence provides a spirally guided motion for the plasma to travel towards the deposition chamber. The density of these plasma beams can be controlled by tuning the strength of the magnetic field at the Y-bend filter. These two plasma beams are combined at the junction of the Y-bend filter and therefore, engage in the first stage of their interaction. Unwanted macro-particles, being neutrally charged, are trapped and filtered by the Y-bend magnetic filter.

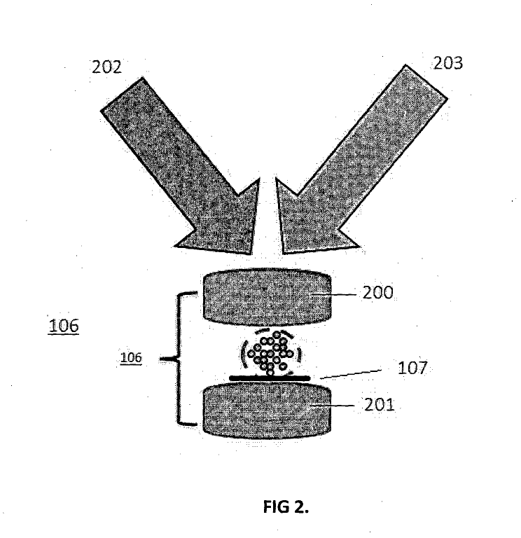

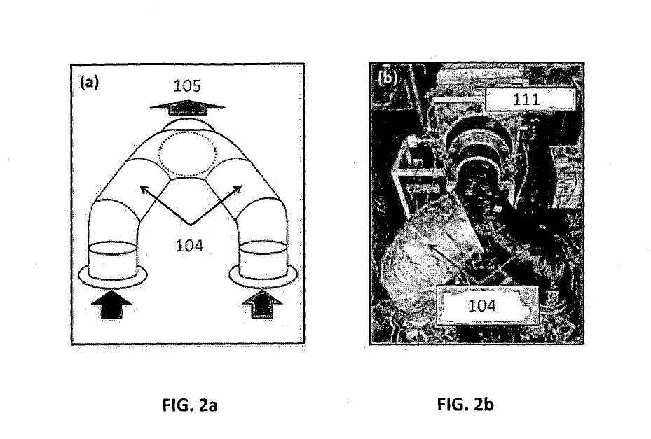

The Y-bend magnetic filter (104), consists of two off-plane double bend magnetic filters (104a, 104b), manufactured as mirror images to each other and partially attached together at the upper end, as shown in FIGS. 2a and 2b. The macroparticle filtering mechanism employed in the Y-bend filter is the same as that used in the off-plane double-bend solenoid magnetic filter disclosed in U.S. Pat. No. 6,031,239 (see column 3, line 39 to column 7, line 25, Examples 1, 3 and 4 and FIGS. 2 and 11 to 15) and U.S. Pat. No. 6,511,585 (disclosing the use of a magnetic filter comprising a baffle with the double-bend filter of U.S. Pat. No. 6,031,239, see FIGS. 1 to 3 and 4(c) and column 7, line 26 to column 8, line 30), which are incorporated herein by reference.

Due to the bending angle of filters used in FCVA systems, the guided plasma beam is usually off-center as it leaves the filter. This is true for conventional FCVA systems with a single plasma beam. This is not a significant problem for single-beam systems because the substrate can be aligned with respect to the plasma beam. However, when two plasma beams are used, each beam deflects to a different off-center position. To ensure that the beams are focused properly onto the magnetic trap discussed below, a focusing coil is used to realign the beams.

The focusing coil is an electromagnetic coil and is connected to a DC power supply. The operational range of the focusing coil is about 10 A and it is placed at the end of the Y-bend magnetic filter, as shown in FIG. 2b. As DC current flows through the coil, a magnetic field perpendicular to the coil is generated that aligns and converges the two plasma beams.

b. Anti-Helmholtz coil and the intermixing of the two plasmas

The second stage of interaction between the two plasmas is established at the magnetic confinement created by the anti-Helmholtz coil within the deposition chamber. The purpose of the magnetic confinement is to condense the density of the intermixed plasmas and therefore increases the probability of the interaction, as illustrated in FIG. 2, which shows plasma (202, 203) from each source (101, 102) being directed towards the anti-Helmholtz coil for plasma confinement. This confinement increases the density of the plasmas and, without wishing to be bound to any particular theory, improves the intermixing between the two plasmas.

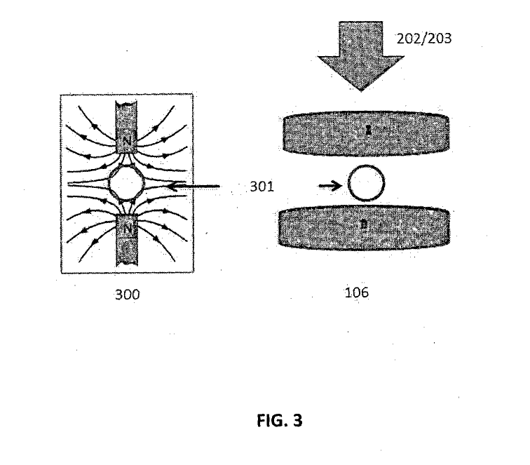

An anti-Helmholtz coil (106) consists of two electromagnet coils (i.e. a first and a second electromagnetic coil; 200, 201), arranged in an anti-parallel configuration. Analogously with a permanent magnet (300), when the magnetic fields from the two coils are aligned in an opposition direction a net field of zero is created at the center of the coils (magnetic trap; 301), as shown in FIG. 3.

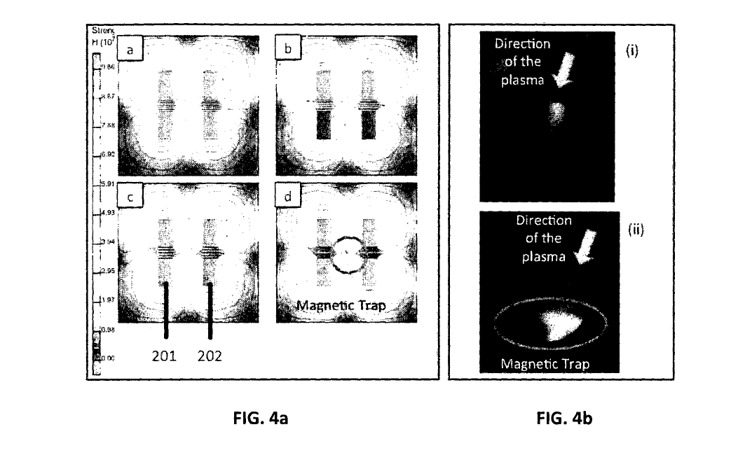

The simulated result from the formation of the magnetic trap can be seen in FIG. 4a. In the simulation FIG. 4a, the electrical current (DC) at coil (200) is set at 10 amps, whereas the current at coil (201) is increased from 2.5 A, 5 A, 7.5 A and 10 A, corresponding to insets a-d in FIG. 4a. Distinctively, a zero field is created at the center of the coils (inset d) as the strength of the two opposing magnetic fields matches and counteracts one another. Due to the formation of this trap, the plasma that has been guided towards the trap is confined and hence the density is increased, as observed by experiment in FIG. 4b, where FIG. 4b(i) shows the density of plasma that has not been trapped in comparison to FIG. 4b(ii), where the plasma has been trapped by magnetic confinement. This condensation in plasma density therefore reduces the mean scattering path of the plasma and enhance the intermixing between the two separate plasmas.

The operational current of the anti-Helmholtz coils is directly proportional to the strength of the magnetic confinement and therefore, the density of the nanoclusters. Increasing the magnetic confinement will cause a decrease in the confinement volume and results in a smaller deposition area. As described below the system disclosed has been tested up to 10 A but higher currents are achievable using a cooling system. As a general guideline, the current of the anti-Helmholtz coils can be anything greater than 0 A up to the maximum current carrying capacity of the coil before it melts down.

In embodiments of the invention, maximum deposition efficiency is achieved when the center of the focusing coil, the anti-Helmholtz coils and the substrate holder are aligned together in a straight line.

In operation, the anode cathode array generates first (101) and second (102) plasma sources are ignited using the strikers (109) and arc sources (110) of the anode-cathode assembly (103) to simultaneously and independently generating a first beam and a second beam of plasma from a first plasma source and a second plasma source, respectively. The resultant first beam of plasma is directed through the first arm (104a) of the Y-bend magnetic filter (104), while the resultant second beam of plasma is directed through the second arm (104b) of the Y-bend magnetic filter (104). The energy of the first beam and the second beam is independently controlled by adjusting the electrical current of the first or second plasma source, respectively.

The first and second beams of plasma intersect and mix together in a first stage interaction in the stem (104c) of the Y-bend magnetic filter (104). The direction of the first beam of plasma and the second beam of plasma is accomplished by the use of magnetic filters attached to the first (104a) and second (104b) arms of the Y-bend magnetic filter (104). Additionally the density of the first beam of plasma and the second beam of plasma is controlled by tuning the strength of the magnetic field of the Y-bend filter.

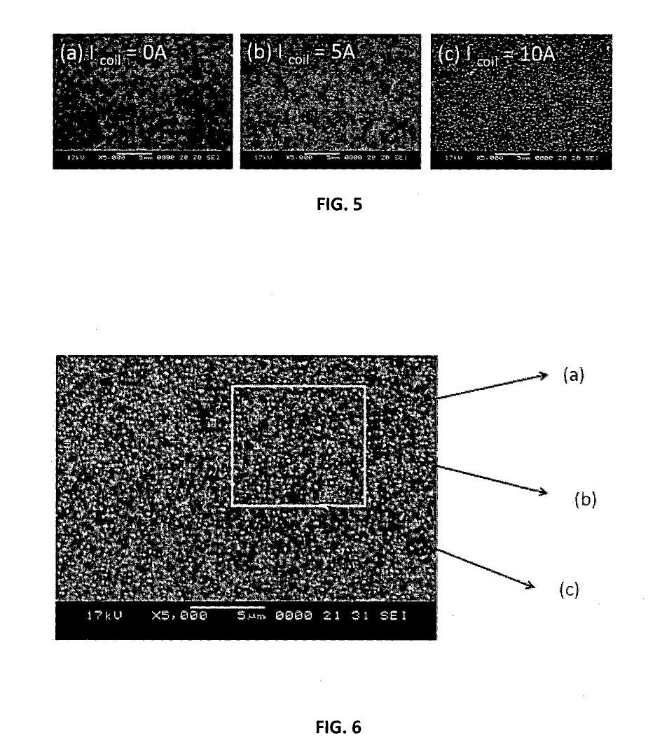

The resultant mixed plasma is then directed towards an electromagnetic magnetic containment field situated in a deposition chamber, optionally the orientation and direction of the beam may be controlled by a focusing coil (111) which helps to align and converge the plasma beams. The magnetic containment field is generated by the electromagnetic coils (200, 201) of the anti-Helmholtz set-up (105), which provide substantially identical electromagnetic fields, and is described herein with reference FIGS. 2 to 4. It is believed that the magnetic trap increases the density and intermixing of the two plasmas in a second stage interation, resulting in the production of superior compound nanoclusters, as shown in FIG. 5 and FIG. 6. Finally, the plasma from the second stage interaction is deposited on a substrate (107) to generate a compound nanocluster film.

The substrate holder (107), which holds the substrate is positioned and oriented so that it is placed within the anti-Helmholtz coils, near to the magnetic trap, as shown in FIG. 2. The distance between the magnet trap and the substrate is inversely proportional to the deposition rate and there will not be any deposition if the substrate is placed too far away from the magnetic trap. In addition an electrical heater is attached onto the substrate holder that is capable of generating up to 600° C.

When discussed herein, the magnetic trap or magnetic confinement is not an absolute confinement. The strength of the magnetic field varies at a gradient, from zero at the center and increases as it moves away from the center of the trap, towards the coil, as shown in the simulation result at FIGS. 4a-d. Therefore, the optimum position of the substrate is determined by a routine trial and error approach. The distance from the magnetic trap has a direct impact on the rate of the deposition, as well as the density of the nanoclusters embedded into the film.

In a typical system according to the invention, the system operates at a base pressure of 2-6×10⁻⁶ Torr, achieved with a rotary pump and a turbo-molecular pump. Three separate DC power sources independently provide electrical current to the Y-bend filter, focusing coil and the anti-Helmholtz coils, respectively, to create the magnetic guiding field and trap. The amount of the current for the Y-bend magnetic filter and the focusing coil are dependent on the magnetic field strength required and different systems may have different requirements.

In an embodiment of the invention, 60 A is supplied to the Y-bend filter, 10 A is supplied to the focusing coil and a current from 0 A to 10 A is supplied to the anti-Helmholtz coils.

To generate and sustain plasma from the material target placed within the anode-cathode assembly, it is necessary to maintain an electrical arcing across the target material and the amount of voltage is material dependent, associated to their ionization energy. Typically for a carbon target and operating voltage of 50V is applied, for a Zinc target the operating voltage will be about 70V and for aluminum the operating voltage will be around 130V.

As discussed in the examples below, the apparatus described above can be used to make:
(a) compound nanocluster thin films;
(b) compound nanocluster thin films suitable as catalysts for the generation of carbon nanotubes with superior properties; and
(c) carbon encapsulated metal nanoclusters that have particularly good magnetic storage properties in a high-temperature environment.

Compound nanocluster thin films have widespread of potential applications in microelectronic⁹, optoelectronics¹⁰, magnetic applications¹¹, gas sensors¹², catalysis¹³ and even biotechnological applications¹⁴.

It is speculated that the use of a compound nanocluster catalyst prepared using the apparatus and process of the currently disclosed application will result in improved thermal boundary resistance between CNT and substrate for use in the production of next-generation thermal interface materials.

Theoretical studies and experimental results have both demonstrated that the thermal boundary resistance between carbon nanotubes and substrate is inversely proportional to their contact surface²⁷. Also, current carbon nanotube growth techniques on many substrates require a barrier layer (typically SiO₂, AlN) to prevent the catalyst layer from diffusing into the substrate during growth. This means that the thermal boundary resistance between the carbon nanotube and the substrate is unnecessarily increased. In order to circumvent this, a hybrid interface layer (e.g. the Ni:C nanocluster thin film embodied in this application) is introduced. By embedding a segment of the base of the carbon nanotubes into a carbon-based matrix, the contact surface area is increased while the barrier layer is minimised. Therefore, it is speculated that the overall thermal performance will significantly improve.

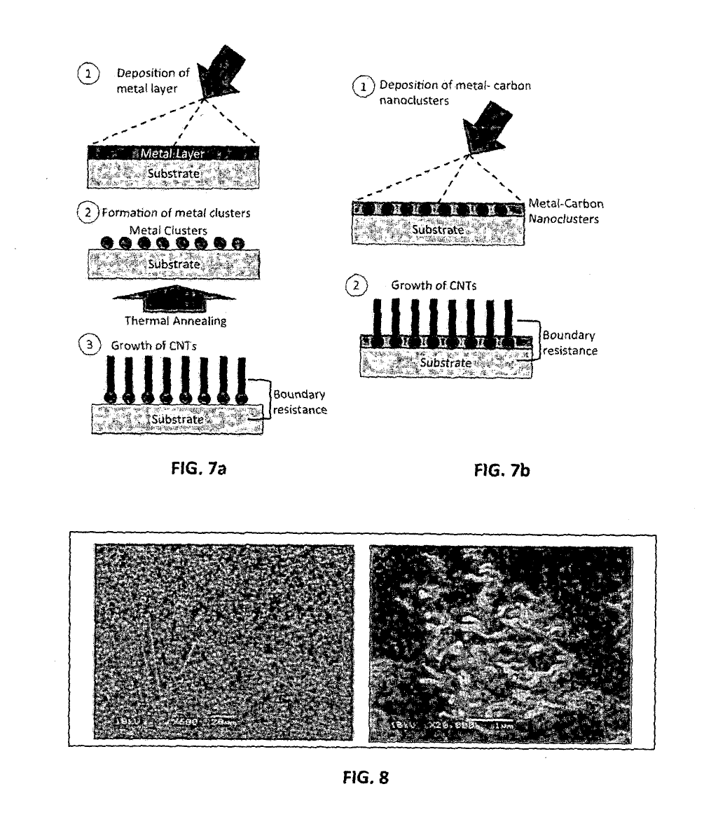

FIG. 7a shows the conventional methodology used to make carbon nanotubes. Carbon nanotubes are conventionally prepared by chemical vapor deposition (CVD) of a metal layer (˜1-10 nm) on a substrate step (1) in FIG. 7a, followed by the formation of metal clusters using thermal annealing (˜600° C.) as shown in step (2) of FIG. 7a to produce metal clusters. Step (3) involves growth of carbon nanotubes from said clusters. As shown in FIG. 7 b the current methodology is simpler in that metal-carbon nanoclusters are formed directly onto the surface of the substrate in step (1) and can be used directly to form carbon nanotubes in step (2) of FIG. 7b.

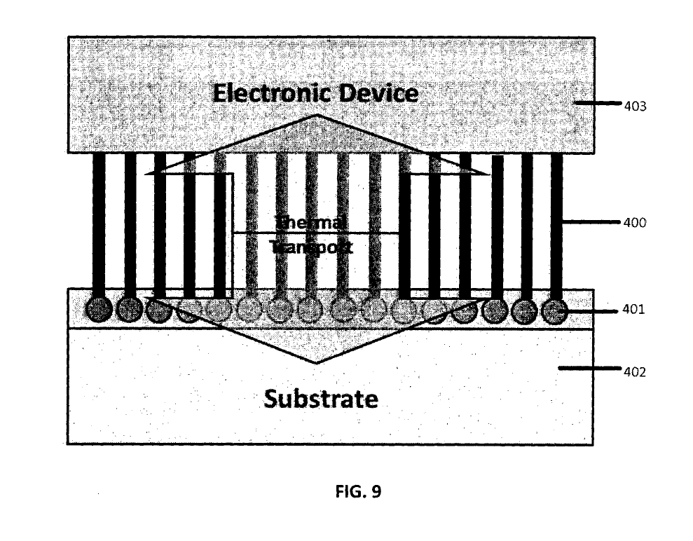

FIG. 9 depicts the use of carbon nanotubes derived from the nanoclusters of the current invention as a carbon-based thermal interface material (TIM). As depicted, the carbon nanotubes (400) are grown from nanoclusters (401) formed on a substrate (402), and said nanotubes are connected to an electronic device (403). The carbon nanotubes provide thermal transport as depicted by the arrow in the figure.

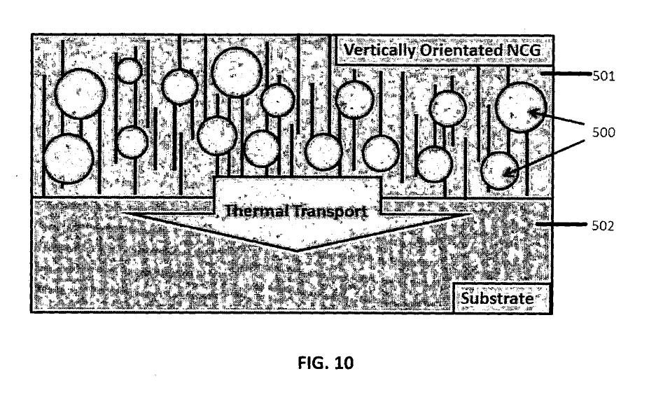

As discussed above, carbon encapsulated metal nanoclusters (particularly carbon encapsulated nickel nanoclusters) are useful in magnetic applications, due to their properties (particularly high-temperature magnetic storage properties in a high temperature environment). FIG. 10 depicts a schematic version of such nanoclusters.

In FIG. 10. the nickel nanoclusters suitable for magnetic storage (500) are encapsulated in vertically oriented nanocrystalline graphite (501) attached to a substrate. As described above for carbon nanotubes, carbon encapsulated nickel nanoclusters are potentially useful in the transport of thermal energy (e.g. as shown by the depicted arrow).

### EXAMPLES

Scanning Electron Microscope (SEM) is used to examine the cluster distribution.

X-Ray Diffraction—XRD is the method to determine the crystal structure of the clusters and the carbon matrix.

High Resolution Transmission Electron Microscopy (HRTEM) is the technique to tell the detail microstructure of the nanocluster film, the detail arrangement of nanocluster and the orientation of the NCG carbon can be seen using this technique.

The operation of FCVA apparatus is initiated by igniting an arc by making momentary contact the target surface (cathode) with a graphite striker connected to anode, the spot is heated rapidly due to the high local current density. A flux of ions with energies exceeding the cathode-anode potential difference and amounting to roughly 10% of the arc current will be emitted from the target arc spots. The ion plasma will then travel through the magnetic filter, and all neutral particles will be filtered away by the filter, only the desired ions will pass through and landed on the deposition substrate in the vacuum chamber. The ions will then form the film with different microstructures (sp², sp³ content, and degree of graphitization) depends on the ion energy (controlled by the substrate bias, heating).

### Example 1

### Formation of a Nanocluster Thin Film

A Metal (Zinc)—Carbon nanocluster film is deposited with the Y-bend FCVA system described herein, with both targets having a purity of 99.99%. Three different conditions of the magnetic trap are tested with the electrical current at both of the electromagnetic coils being adjusted to 0 A, 5 A and 10 A. The thickness of each deposited film is 100 nm, approximately. The scanning electron microscopy (SEM) images of these films are shown in FIG. 5. Clearly, an increment of the nanocluster density (brighter spots) can be observed as the strength of the magnetic field is increased.

To verify the chemical characteristic of these deposited nanocluster films, energy-dispersive X-ray (EDX) spectroscopy is performed on the material deposited using the anti-Helmholtz coils at a current of 10 A (also depicted in FIG. 5C) and the result is shown in FIG. 6. Point scan (a) provides an EDX result showing the atomic ratio of Zn/C is around 1.0, point scan (b) provides an EDX result showing the atomic ratio of Zn/C is around 0.4 and area scan (c) provides an EDX result showing the atomic ratio of Zn/C is around 0.6. This measurement confirms that the brighter spots correspond to Zn clusters whereas the darker region represents carbon. The relative density between Zn clusters and carbon is also found to be ˜60% (as shown in EDX area scan (c)).

### Example 2

In a conventional carbon nanotube (CNT) synthesis approach, a thin layer of catalytically active metal layer (˜10 nm) is firstly deposited onto the substrate and subsequently, a thermal annealing process at the range of 550-600° C. This annealing process is to transform the thin layer of metal into island-like nanostructures. The diameters of these island-like structures are typically in the range of 10 nm. For the growth of CNTs, the nanostructure film then undergoes a chemical vapor deposition (CVD) process by having chemical reaction with C₂H₂ and NH₃ in a controlled environment at 650-700° C. The diameter of the grown CNTs is closely related to the diameter of the island-like nanostructure.

In the current example, Cobalt (Co) is used as the catalytically active metal and it is directly embedded into the carbon matrix film as a form of nanoclusters, identical to the previously mentioned island-like nanostructures, using the FCVA apparatus of this invention. This deposition process is performed by having one source as Co (at 90V) and the other source as carbon (at 50V). To synthesise CNTs, the nanocluster film undergoes the same CVD process with C₂H₂ and NH₃ at 650° C. as per the conventional method. By varying the strength of the magnetic trap (0-10A), the density of the nanoclusters varies, which corresponds directly to the density of the grown CNTs. An advantage of this approach is that the island-like nanostructures are now embedded within the carbon matrix, therefore, the contact surface area is increased and as a result, the electrical/thermal boundary resistance between the CNTs and the substrate is reduced.

The SEM image of the CNTs synthesized with the nanocluster film described above is shown in FIG. 8, and as a result of the nanocluster catalyst, CNTs bundles are formed.

### Example 3

We have successfully infused Nickel (Ni) nanoclusters into vertically orientated nanocrystalline graphite (NCG) film to study its potential for high temperature magnetic storage applications, as shown in the schematic in FIG. 10, as discussed hereinbefore.

For the application of high-density magnetic storage, we embed Nickel (Ni) nanoclusters into a NCG matrix. Since the objective is to increase the magnetic storage capacity, the magnetic trap operates at its maximum strength (10A) to deliver a high density Ni nanocluster thin film. Ni (at 90V) is used one of the sources and carbon (at 50V) is used for the other. A substrate temperature of 400° C. is applied during the deposition process in order to produce the NCG film.²⁸

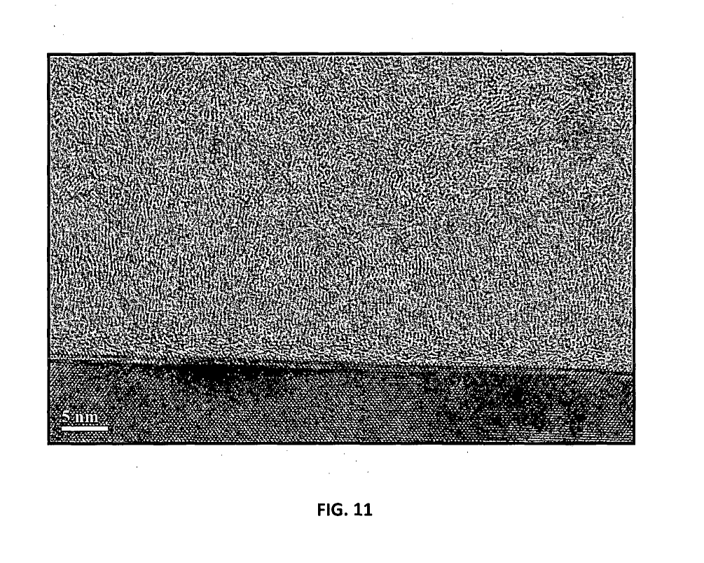

FIG. 11 shows the cross sectional transmission electron microscopy (TEM) images of Ni infused nanocrystalline carbon thin film. The dark circular structures correspond to Ni nanoclusters while the lighter grey region corresponds to carbon film and the darker grey region at the bottom of the image corresponds to the substrate. Within the carbon film, multiple basal planes can be seen with its orientation perpendicular to the substrate, a typical signature for NCG film.

### REFERENCES

1. Patents of the FCVA Technology (Nanyang Technological University, Singapore)

i Filtered cathodic arc source (1995) Description : Invention of double bend solenoid filter Shi X, Flynn D, Tay B K, Tan H S Patent No: U.S. Pat. No. 6,031,239

ii Filtered cathodic arc source deposition apparatus (1995) Description: Invention of FCVA coating system to deposit amorphous diamond films Flynn D, Fulton M, Shi X, Tan H S, Tay B K Patent No: US 2003085123

iii Cathodic arc source and graphite target (1996) Description: Invention of electromagnetic field configuration used for FCVA technology Shi X, Tan H S, Tay B K Patent No: UK 97932940.6

iv Cathodic arc source with target feeding apparatus (1997) Description: Invention of continuous target feeding for production of amorphous diamond coating Shi X, Tay B K, Tan H S Patent No: U.S. Pat. No. 6,262,539

v Enhanced Macroparticle filter And cathodic Arc Source (1997) Description: Invention of filter to improve filtering efficiency for FCVA technology Shi X, Tay B K, Tan H S Patent No: U.S. Pat. No. 6,511,585

vi Cathodic Arc Source For Metallic and Dielectric coatings (1997) Description: Invention of metal and dielectric coatings using FCVA technology Shi X, Tay B K, Tan H S Patent No: U.S. Pat. No. 6,413,387

vii Composite Coatings (1999) Description: Invention of carbon based composite coatings using FCVA technology Shi X, Tan H S, Tay B K Patent No: U.S. Pat. No. 6,143,142

viii Ignition Means for a cathodic arc source (1995) Flynn D, Shi X, Tan HS, Tay B K Patent No: U.S. Pat. No. 6,319,369

ix Heat Transfer Surface (1999) Description: Heating element having a heat transfer surface comprising a layer of tetrahedral amorphous carbon and/or diamond-like carbon, and for a composite such a heating element has a prolonged service life and requires less frequent cleaning to remove deposits which may otherwise cause a reduction in the heat coefficient of the element and an increase in the consumption of electricity Shi X, Tan HS Patent No: U.S. Pat. No. 6,571,865

x Low Fouling & Drop-wise Coatings for Heat Exchangers (1999) Description: Invention of coating process for dropwise condensation Shi X, Tan H S, Tay B K Patent No:

xi Arc Monitoring (1997) Description: Invention on the control and monitoring of FCVA process Shi X, Jin X Z, Tan H S Patent No: U.S. Pat. No. 6,338,779

xii Field Emission Device and Method of Fabricating Same (2001) Description: A method of fabrication a field emission component for use in flat panel displays and vacuum microelectronics applications Sun Z, Tay B K, Li Y J, Lau S P Patent No:

2) B. K. Tay, Z. W. Zhao, and D. H. C. Chua, “Review of metal oxide films deposited by filtered cathodic vacuum arc technique”, Mat. Sci. Eng. R., 52(1-3), 1-48, (2006).

3) Julio A. Alonso, “Structure and properties of atomic nanoclusters”, Imperial College Press, (2005).

4) Ott, L. S. & Finke, R. G. Transition-metal nanocluster stabilization for catalysis: A critical review of ranking methods and putative stabilizers. Coord. Chem. Rev. 251, 1075-1100 (2007)

Narayanan, R. & El-Sayed, M. A. Effect of catalysis on the stability of metallic nanoparticles: Suzuki reaction catalyzed by PVP-palladium nanoparticles. J. Am. Chem. Soc. 125, 8340-8347 (2003).

Jiao J; Seraphin S, “Carbon encapsulated nanoparticles of Ni, Co, Cu, and Ti”, J APPL PHYS, 83, (5), 2442-2448, 1998

5) Kirchhoff, M., Specht, U. & Veser, G. Engineering high-temperature stable nanocomposite materials. Nanotechnology 16, S401-S408, (2005).

6) Qun H., James G. W., “Monofuntional gold nanoparticles: synthesis and applications”, J. Nanopart. Res., 9 (6), 1013-1025, (2006).

7) Andre A., “Metal plasma immersion ion implantation and deposition: a review”, Surf. Coat. Technol.,93, (2-3), 158-167,(1997).

8) K. Wegner, P. Piseri, H. Vahedi Tafreshi and P. Miliani, “Cluster beam deposition: a tool for nanoscale science and technology”, J. Phys. D: Appl. Phys. 29, R439-R459. (2006).

9) Ostraat M. L., De Blauwe J. W., Green M. L., Bell L. D., Atwater H. A. and Flagan R. C., “Ultraclean two-stage aerosol reactor for production of oxide-passivated silicon nanoparticles for novel memory devices”, J. Electrochem. Soc., 148, G265-70, (2001).

10) Huisken F., Ledoux G. Guillois O and Reynaud C., “Light-Emitting Silicon Nanocrystals from Laser Pyrolysis”, Adv. Mater., 14, 1861-5, (2002).

11) Qui J. M., Xu Y. H., Judy J. H. and Wang J. P., “Nanocluster deposition for high density magnetic recording tape media”, J. Appl. Phys., 97, 10P704, (2005).

12) Madler L. Roessler A., Pratsinis S. E., Sahm T., Gurlo A., Barsan N and Weimar U., “Direct formation of highly porous gas-sensing films by in situ thermophoretic deposition of flame-made Pt/SnO2 nanoparticles” Sensors Actuators B, 114, 283-95, (2006).

13) Takeuchi M., Dohshi S., Eura T. and Anpo M., “Preparation of Titanium-Silicon Binary Oxide Thin Film Photocatalysts by an Ionized Cluster Beam Deposition Method. Their Photocatalytic Activity and Photoinduced Super-Hydrophilicity”J. Phys. Chem. B, 107, 14278-82, (2003).

14) Collins J. A., Xirouchaki C., Palmer R. E., Heath J. K. and Jones C. H., “Clusters for biology: immobilization of proteins by size-selected metal clusters”, Appl. Surf. Sci., 226, 197-208, (2004).

15) Robertson J., “Growth of nanotubes for electronics.”, Materials Today, 10, 36-43, (2007).

16) Prasher R., “Thermal boundary resistance and thermal conductivity of multiwalled carbon nanotubes.”, Phys. Rev. B, 77, 075424-1, (2008).

17) Lu Y, Zhu Z, Liu Z. Carbon-encapsulated Fe nanoparticles from detonation-induced pyrolysis of ferrocene. Carbon. 43(2):369-74,(2005).

18) Ang K H, Alexandrou I, Mathur N D, Amaratunga G A J, Haq S. The effect of carbon encapsulation on the magnetic properties of Ni nanoparticles produced by arc discharge in de-ionized water. Nanotechnology. 15(5):520, (2004).

19) Subramoney S. Novel nanocarbons—Structure, properties, and potential applications. Advanced Materials. 10(15):1157-+, (1998)

20) Ang K H, Alexandrou I, Mathur N D, Amaratunga G A J, Haq S. The effect of carbon encapsulation on the magnetic properties of Ni nanoparticles produced by arc discharge in de-ionized water. Nanotechnology.15(5):520, (2004).

21) Huh S H, Nakajima A. Laser synthesis and magnetism of amorphous iron and cobalt carbide nanoparticles with carbon onion. Journal of Applied Physics.99(6):064302-5. (2006)

22) Leonowicz M, Woźniak M, Shulga Y M, Muradyan V E, Liu Z, Davies H A, et al. Structure and magnetic properties of nanoparticles encapsulated in carbon shells. J Magn Magn Mater. 294(2):e57-e62, (2005).

23) Oliete P B, Cristina Rojas T, Fernandez A, Gedanken A, Koltypin Y, Palacio F. Characterisation and magnetic behaviour of nickel nanoparticles encapsulated in carbon. Acta Materialia. 52(8):2165-71, (2004)

24) Hayashi T, Hirono S, Tomita M, Umemura S. Magnetic thin films of cobalt nanocrystals encapsulated in graphite-like carbon. Nature. 381(6585):772-4, (1996).

25) Shakerzadeh M, Loh GC, Xu N, Chow W L, Tan C W, Lu C, et al. Re-ordering Chaotic Carbon: Origins and Application of Textured Carbon. Advanced Materials. 24(30):4112-23, (2012)

26) Shakerzadeh M., Samani M. K. , Khosravian N., Teo E. H. T., Bosman M., Tay B. K., Thermal conductivity of nanocrystalline carbon films studied by pulsed photothermal reflectance, Carbon Volume: 50 Issue: 3 Pages: 1428-1431, (2012)

27) H. M. Duong, S. T. Nguyen, Limiting mechanisms of thermal transport in carbon nanotube-based hetrogeneous media, Recent Patents on Engineering, 2011,3, p.209-232

28) M. Shakerzadeh, G. C. Loh, N. Xu, W. L. Chow, C. W. Tan, C. Lu, R. C. C. Yap, D. Tan, S. H. Tsang, E. H. T. Teo , B. K. Tay, Re-ordering Chaotic Carbon: Origins and Application of Textured Carbon, Adv. Mater. 2012 Aug. 8;24(30):4112-2 (2012)

1. A filtered cathodic vacuum arc (FCVA) apparatus for the generation of a nanocluster film or a compound film on a substrate, comprising:
a deposition chamber;
a substrate holder for holding a substrate;
means for simultaneously generating a first beam of plasma and a second beam of plasma from a first and a second plasma source, respectively;
a Y-bend magnetic filter that connects the first and second plasma sources with the deposition chamber, the Y-bend filter comprising a single stem, a first arm and a second arm, with the first arm connecting the first plasma source to the stem, and the second arm connecting the second plasma source to the stem, and the stem connecting the first and second arms to the deposition chamber, at least the first and second arms containing respective magnetic field generation means for guiding the first beam of plasma and the second beam of plasma respectively along the first and second arms; and
an anti-Helmholtz coil set-up within the deposition chamber that is adapted to provide a magnetic confinement for the plasma generated from the first and second plasma sources, and which comprises a first and a second electromagnetic coil, wherein,
the Y-bend magnetic filter is adapted to channel the plasma from the first and second plasma sources together in a first stage interaction and the anti-Helmholtz coil set-up is adapted to establish a second stage interaction between the respective the first and second plasmas by magnetic confinement.

2. The apparatus of claim 1, wherein the Y-bend magnetic filter further comprises a focusing coil attached to the stem.

3. The apparatus of claim 1, wherein the first and second arms of the Y-bend magnetic filter each comprises a first bend and a second bend.

4. The apparatus according to claim 1, wherein the means for simultaneously generating a beam of positive ions in the form of plasma from a first and a second plasma source is a first anode-cathode assembly attached to the first plasma source and a second anode-cathode assembly attached to the second plasma source.

5. The apparatus according to claim 1, wherein the first plasma source is carbon and the second plasma source is a metal, optionally wherein the second plasma source is selected from zinc, nickel, aluminium and iron.

6. The apparatus according to claim 1, wherein the first plasma source is a metal, the second plasma source is a metal, wherein the first and second plasma sources are selected from zinc, nickel, aluminium and iron, provided that the first and second sources are not the same metal.

7. The apparatus according to claim 1, wherein the apparatus further comprises:
means for independently controlling the energy of the first and second plasma beams, optionally wherein the means is supplied by a first and second current controlled attached to the first plasma source and the second plasma source, respectively; and/or
means for independently controlling the density of the first and second plasma beams, optionally wherein the means is supplied by a first and second tuning controller that tune the magnetic field produced in the first arm and the second arm of the Y-bend magnetic filter, respectively.

8. The apparatus according to claim 1, wherein the anti-Helmholtz coil further comprises a current controller for independent control of the first and second electromagnetic coils.

9. The apparatus according to claim 1 wherein the substrate holder is positioned within the anti-Helmhotz coil, whereby in operation the substrate is proximate or within a magnetic trap produced by the anti-Helmholtz coil.

10. The apparatus of claim 9 wherein the substrate holder is positioned proximate the magnetic trap.

11. A process for the deposition of a compound nanocluster film onto a substrate, using of a filtered cathodic vacuum arc (FCVA) apparatus for the generation of a nanocluster film or a compound film on a substrate, comprising:
a deposition chamber;
a substrate holder for holding a substrate;
means for simultaneously generating a first beam of plasma and a second beam of plasma from a first and a second plasma source, respectively;
a Y-bend magnetic filter that connects the first and second plasma sources with the deposition chamber, the Y-bend filter comprising a single stem, a first arm and a second arm, with the first arm connecting the first plasma source to the stem, and the second arm connecting the second plasma source to the stem, and the stem connecting the first and second arms to the deposition chamber, at least the first and second arms containing respective magnetic field generation means for guiding the first beam of plasma and the second beam of plasma respectively along the first and second arms; and
an anti-Helmholtz coil set-up within the deposition chamber that is adapted to provide a magnetic confinement for the plasma generated from the first and second plasma sources and which com rises a first and a second electromagnetic coil wherein
the Y-bend magnetic filter is adapted to channel the plasma from the first and second plasma sources together in a first stage interaction and the anti-Helmholtz coil set-up is adapted to establish a second stage interaction between the respective the first and second plasmas by magnetic confinement,
the process comprising the steps of:
(a) simultaneously and independently generating a first beam and a second beam of plasma from a first plasma source and a second plasma source, respectively;
(b) independently directing the first beam and second beam of plasma through a first arm and second arm, respectively, of a Y-bend magnetic filter towards a connective stem of the Y-bend magnetic filter fluidly connected to both arms;
(c) mixing the first and second beams of plasma together in the connective stem of the Y-bend magnetic filter in a first stage interaction;
(d) directing the mixed plasma of the first stage interaction towards an electromagnetic magnetic containment field situated in a deposition chamber;
(e) further mixing the mixed plasma of the first stage interaction together in a second stage interaction within the electromagnetic containment field; and
(f) depositing the mixed plasma generated by the second stage interaction onto a substrate situated in the deposition chamber to form a compound nanocluster film.

12. The process of claim 11, wherein the magnetic containment field is generated by said anti-Helmhotz coil set-up, said first and second electromagnetic coils independently producing substantially identical but opposed electromagnetic fields.

13. The process of claim 12, wherein the first and second electromagnetic coils operate using a current from 0.5 A to 20 A, optionally from 2.5 A to 15 A, such as from 5 A to 10 A.

14. The process of claim 11, further comprising a step (g) where carbon nanotubes are formed from the compound nanocluster film deposited onto the substrate in step (f) of claim 8.

15. The process of claim 14, wherein the nanocluster film is made of cobalt nanoclusters embedded in a carbon matrix and the carbon nanotubes are formed by a chemical vapour deposition process using C₂H₂ and NH₃ at 650° C.

16. The process of claim 11, further comprising forming a nickel encapsulated nanoclusters in a nanocrystalline graphite matrix, wherein carbon is the first source, nickel is the second source and a substrate temperature of 400° C. is applied during the deposition process.

17. The process of claim 11, wherein the first plasma source is carbon and the second plasma source is a metal, optionally wherein the second plasma source is zinc, nickel, aluminium and iron.

18. The process of claim 11, wherein the first plasma source is a metal and the second plasma source is a metal, optionally wherein the first and second plasma sources are selected from zinc, nickel, aluminium and iron, provided that the first and second plasma sources are not the same metal.

19. The process of claim 11, wherein:
(i) in step (a) of claim 11, the generation of the first beam and second beam of plasma is accomplished by the use of a first and second anode-cathode array attached to the first and second plasma source, respectively; and/or
(ii) in step (a) of claim 11, the energy of the first beam and the second beam is independently controlled by adjusting the electrical current of the first or second plasma source, respectively; and/or
(iii) in step (b) of claim 11, the direction of the first beam of plasma and the second beam of plasma is accomplished by the use of magnetic filters attached to the first and second arms of the Y-bend magnetic filter; and/or
(iv) in step (b) of claim 11, the density of the first beam of plasma and the second beam of plasma is controlled by tuning the strength of the magnetic field of the Y-bend filter; and/or (v) in step (d) of claim 11, the direction of the mixed plasma of the first stage interaction is accomplished by a focusing coil attached to the connective stem of the Y-ben magnetic filter
(vi) in step (f) of claim 11, the deposition is further controlled by the use of a substrate heater affixed to the substrate holder and adapted to supply heat to the substrate.

20. A compound nanocluster thin film and/or compound nanocluster thin film catalyst for the synthesis of carbon nanotubes or a carbon encapsulated metal nanocluster obtained or obtainable by a process for the deposition of a compound nanocluster film onto a substrate, using of a filtered cathodic vacuum arc (FCVA) apparatus for the generation of a nanocluster film or a compound film on a substrate, comprising:
a deposition chamber;
a substrate holder for holding a substrate;
means for simultaneously generating a first beam of plasma and a second beam of plasma from a first and a second plasma source, respectively;
a Y-bend magnetic filter that connects the first and second plasma sources with the deposition chamber, the Y-bend filter comprising a single stem, a first arm and a second arm, with the first arm connecting the first plasma source to the stem, and the second arm connecting the second plasma source to the stem, and the stem connecting the first and second arms to the deposition chamber, at least the first and second arms containing respective magnetic field generation means for guiding the first beam of plasma and the second beam of plasma respectively along the first and second arms; and
an anti-Helmholtz coil set-up within the deposition chamber that is adapted to provide a magnetic confinement for the plasma generated from the first and second plasma sources, and which comprises a first and a second electromagnetic coil, wherein,
the Y-bend magnetic filter is adapted to channel the plasma from the first and second plasma sources together in a first stage interaction and the anti-Helmholtz coil set-up is adapted to establish a second stage interaction between the respective the first and second plasmas by magnetic confinement,
wherein the process comprises the steps of:
(a) simultaneously and independently generating a first beam and a second beam of plasma from a first plasma source and a second plasma source, respectively;
(b) independently directing the first beam and second beam of plasma through a first arm and second arm, respectively, of a Y-bend magnetic filter towards a connective stem of the Y-bend magnetic filter fluidly connected to both arms;
(c) mixing the first and second beams of plasma together in the connective stem of the Y-bend magnetic filter in a first stage interaction;
(d) directing the mixed plasma of the first stage interaction towards an electromagnetic magnetic containment field situated in a deposition chamber;
(e) further mixing the mixed plasma of the first stage interaction together in a second stage interaction within the electromagnetic containment field; and
(f) depositing the mixed plasma generated by the second stage interaction onto a substrate situated in the deposition chamber to form a compound nanocluster film,
wherein the first plasma source is carbon and the second plasma source is a metal, optionally wherein the second plasma source is zinc, nickel, aluminium and iron.

21.-22. (canceled)
